(19) United States
(12) Patent Application Publication
(10) Pub. No.: US 2010/0182044 A1
(43) Pub. Date: Jul. 22, 2010

(54) PROGRAMMING AND CIRCUIT TOPOLOGIES FOR PROGRAMMABLE VIAS

(75) Inventor: Herman Schmit, Palo Alto, CA (US)

Correspondence Address: CONNOLLY BOVE LODGE & HUTZ LLP, 1875 EYE STREET, N.W., SUITE 1100, WASHINGTON, DC, 20006, US

(73) Assignee: eASIC Corporation, Santa Clara, CA (US)

(21) Appl. No.: 12/732,436

(22) Filed: Mar. 26, 2010

Related U.S. Application Data
(63) Continuation-in-part of application No. 12/046,626, filed on Mar. 12, 2008.
(60) Provisional application No. 60/894,548, filed on Mar. 13, 2007.

(51) Int. Cl. H03K 19/094

(52) U.S. Cl. 326/49

(57) ABSTRACT

A semiconductor device may be created using multiple metal layers and a layer including programmable vias that may be used to form various patterns of interconnections among segments of metal layers. The programmable vias may be formed of materials whose resistance is changeable between a high-resistance state and a low-resistance state.

### CROSS-REFERENCE TO RELATED APPLICATION

This application is a continuation-in-part of co-pending U.S. patent application Ser. No. 12/046,626, filed on Mar. 12, 2008, which claims the priority of U.S. Provisional Patent Application No. 60/894,548, filed on Mar. 13, 2007, both of which are incorporated by reference herein in their entireties.

### FIELD OF ENDEAVOR

Various embodiments of the invention may involve layout, circuit design, and programming methodologies for programmable. vias.

### BACKGROUND

Broadly defined, structured application-specific integrated circuits (ASICs) may attempt to reduce the effort, expense and risk of producing application-specific integrated circuits (ASIC) by standardizing portions of the physical implementation across multiple products. By amortizing the expensive mask layers of the device across a large set of different designs, the non-recurring engineering (NRE) seen by a particular customer for a customized ASIC can be significantly reduced. There may be additional benefits to the standardization of some portion of mask set, which may include improved yield through higher regularity and/or reduced manufacturing time from tape-out to packaged chip.

Compared to a field-programmable gate array (FPGA), the unit price of a structured ASIC solution may be reduced by an order of magnitude due to the removal of the storage and logic required for configuration storage and implementation. The unit cost of a structured ASIC may be somewhat higher than a full custom ASIC, primarily due to the imperfect fit between design requirements and a standardized base layer, with certain I/O, memory and logic capacities.

Structured ASIC products may be differentiated by the point at which the user customization occurs and how that customization is actually implemented. Most structured ASICs may only standardize transistors and the lowest levels of metal. A large set of metal and via masks may be needed in order to customize a product. This yields a marginal cost reduction for NRE. Manufacturing latency and yield benefits may also be compromised using this approach.

In some prior patents, all but one via layer in the mask set may be standardized. This single via layer may be implemented, for example, using one of at least two approaches:

A prototyping flow using direct-write e-beam technology may be used to eliminate the need for any mask layers.

A production flow may use a mask layer for the vias.

The disadvantage of structured ASICs compared to FPGAs is that FPGAs do not require any user design information during manufacturing. Therefore, FPGA parts can be manufactured in larger volumes and can exist in larger inventories. This allows the latency of getting parts to customers in the right volumes to be reduced. FPGAs can also be modified after their initial configuration, which means that design bugs can be removed without requiring a fabrication cycle. Design improvements can be made in the field, and even done remotely, which removes the requirement of a technician to physically interact with the system.

An ideal ASIC device may combine the field programmability of FPGAs with the power and size efficiency of ASICs or structured ASICs.

Numerous recently developed technologies can be used to create programmable, two-terminal switches with two or more stable, non-volatile states. Phase change memory materials may be used to store information reaching one of two physical phases: either an amorphous phase that may have high resistivity or a crystalline phase that may have low resistivity (while this is a typical way in which phase change memory materials work, the further possibility is envisioned of an atypical phase change memory material that may work in the opposite fashion or in some other fashion, and which may still be utilized in embodiments of the invention). One of the materials that may be used is chalcogenide. This material is often used, for example, in CD-RW and DVD-RW technology, where the phase change is performed by heating and cooling with a laser beam. It is also possible to change the state with an electric current. A high current may be used to create a higher temperature, and the material may then cool to the amorphous phase with a higher resistance. A medium current may be used to change the cooling to the crystalline phase with a lower resistance. A low current can be used to sense the resistance of the material without changing the phase of the material. This technology is patented and licensed by a company called Ovonyx.

There are other phase-change materials, such as oxide-based solid electrolytes. Memories using such technologies are sometimes referred to as Programmable Metallization Cells (PMCs).

More recently, carbon graphene sheets have been demonstrated to have highly resistive and highly conductive states. These two states can be reached by first creating a break in the graphene sheet with a breakdown voltage. After the breakdown voltage causes a break in the sheet, applying a second voltage, called the write voltage, which is lower than the breakdown voltage, restores the connectivity of the sheet. A voltage between the breakdown and write voltage, called the erase voltage, returns the material to a non-conductive state. The conductive or non-conductive state of the material is non-volatile. It remains in the same state that it was in when the write or erase voltage is removed. Smaller voltages can be applied to the material without affecting the state. This material has been demonstrated to behave this way when deposited in a traditional lithography-etched via hole and covered by a metal electrode.

Other resistive memory technologies behave in similar ways. Specifically, numerous metal-oxide combinations have been shown to exhibit non-volatile bistable behavior where one state is highly resistive, and the second state is conductive.

A combination of resistive memory technology and via-configured structured ASICs can be used to offer an improved customizable integrated circuit, with low cost, area, and power of the structured ASIC, and the field programmability of an FPGA. Unfortunately, the characteristics of these materials are not perfectly suited to integration into programmable semiconductor devices. Some of the shortcomings of these materials are:
ON resistance that is not zero. Ideally, vias would have a resistance similar to metal vias: from 1 to 20 ohms.
OFF resistance is not infinite. Depending on the material, the ratio of OFF to ON resistance is anywhere from one thousand to one million, but it is not infinite. Generally, the OFF or ON resistance value can be varied by manipulating the geometry, doping, interconnect, etc, of the surrounding circuits, but the ratio of OFF to ON resistance is a function of the material. The impact of finite OFF resistance is leakage current, which can add to signal noise and excess power consumption. p1 The programming voltages that are required to change the state of these materials are of a magnitude that can damage standard transistors in an IC.
The programming voltage function, or the voltage as a function of time or current, can be complex to generate and deliver to the programmable via.
Layout of the IC is complicated by the requirement to provide a set of transistors to configure the vias. The vias may be located in a higher level of metal, and the transistors are always located at the base layer.
The number of extra devices necessary to program a programmable via, can exceed the benefit. If, for example, one or two transistors are required to program each programmable via, the transistors should just be used to create the switch.

### SUMMARY OF EMBODIMENTS OF THE INVENTION

Programmable via materials can have significant resistance in the ON state (ON resistance). In graphene-filled vias, resistances of thousands or tens of thousands of ohms have been reported. These resistances are much higher than the resistances in metal vias. In order to minimize the impact of these resistances on circuit performance, they may be used at the end of a signal net. That way, the capacitance that must drain through the programmable via may be minimized. A programmable via fabric architecture with good timing characteristics may have one or more programmable vias at the terminus of the net.

The actual programming of programmable vias using graphene or similar materials may often use higher voltage than may be tolerable by traditional CMOS circuits. In some embodiments of the invention, the sensitive gate oxides may be isolated by using pull-down transistors on the receiving side of any net. The driver side may then have to tolerate the high programming voltage. Since drivers may not typically connect sensitive gate oxide, this may be more tolerable, but to prevent further damage, thick-oxide devices may be used, either as the actual driver transistors, or in series with the net to isolate the driver circuit.

Generating the programming voltage on chip may need to be done carefully because DC supplies at the programming voltage may not be available in a modem digital system. In addition, a current spike may be caused when the programmable via switches from an OFF-state to an ON-state, and this current spike may damage numerous components in the integrated circuit. To solve this problem, embodiments of the present invention may use one or more capacitors to hold adequate voltage for the programming of the device, and the capacitance may serve to limit the current spike that may occur when the program state switches from OFF to ON. The capacitor can be the output stage of a charge pump, which can be used to generate the programming voltage, and can even be used to manipulate the voltage ramp function.

Programming the programmable vias may also require circuitry to provide the programming voltages to just the desired vias. The overhead of this can be substantial. Embodiments of the present invention may reduce this overhead by decoding the desired via by allocating one configuration transistor or other switch device at the sink of a net segment, and another transistor at the source of a net segment. Because multiple sources can potentially connect to a given sink through a programmable via, one may enable a unique programmable via by enabling the transistor or switch device at the source of the net and the transistor at the sink of the net. This may significantly reduce the number of transistors required to program the vias.

The set of programmable vias can be programmed using decoders to enable the programming voltage to be applied to a single programmable via. The set of programmable vias on a single chip can be separated into different subsets, with each subset programmed by having a single pull-up decoder, which may route the programming voltage to a particular programming pull-up transistor, and a pull-down decoder, which may enable one of the pull-down transistors to connect the second terminal of the programmable via to the ground. This partitioning may serve to increase the speed of programming.

Setting programmable vias into an ON or OFF stage may require the application of a voltage function. That voltage may often be higher than those voltages available in typical digital semiconductors. In addition, the higher voltages may damage the transistors in those semiconductors. Therefore, these voltages may need to be generated internally to the device and may also need to be segregated from the vulnerable circuits.

To generate a voltage higher than the input voltage, one may choose a charge-pump for this requirement. Charge pumps may often have input controls, such as frequency sources, that can be used to provide not only the programming voltage, but by manipulating the controls, it may be possible to provide an optimal voltage ramp as a function of time for reliable programming.

Efficient layout of a device having programmable vias is made challenging by the fact that transistors, which may typically exist on the diffusion layer, may often be many metal layers away from the optimal via layer for programmable interconnect. One solution to this may be to use a stack of non-programmable vias to connect transistors and wire segment that connects to programmable vias. However, some embodiments of the present invention may not use a stack, but rather may use an alternation of non-programmable vias and wire segments to implement the span of a programmable net.

Programmable vias may be placed on different layers according to their function. Vias that connect directly to the transistors may be placed close to the diffusion layer, and vias that are primarily dedicated to interconnect may be higher in the metal stack. A chip that consists of multiple layers of programmable vias, therefore, may enable the optimal location of those vias.

### BRIEF DESCRIPTION OF THE DRAWINGS

Various embodiments of the invention will now be described, with reference to the accompanying drawings, in which:

FIG. 1 shows an exemplary schematic of a building block of a programmable fabric using one or more programmable vias, in accordance with an embodiment of the present invention;

FIG. 2 shows an exemplary programming circuit for an integrated circuit (IC) using programmable vias, according to an embodiment of the invention;

FIG. 3 shows an exemplary programming circuit that may be used in various embodiments of the invention;

FIG. 4 shows an embodiment of a circuit having a programmable power supply, in accordance with some embodiments of the invention;

FIGS. 5A and 5B show circuit schematics of examples in which programming transistors are coupled to decoders, in accordance with an embodiment of the invention; and

FIG. 6 illustrates some layout-related aspects of exemplary circuits according to various embodiments of the invention.

### DETAILED DESCRIPTION OF VARIOUS EMBODIMENTS OF THE INVENTION

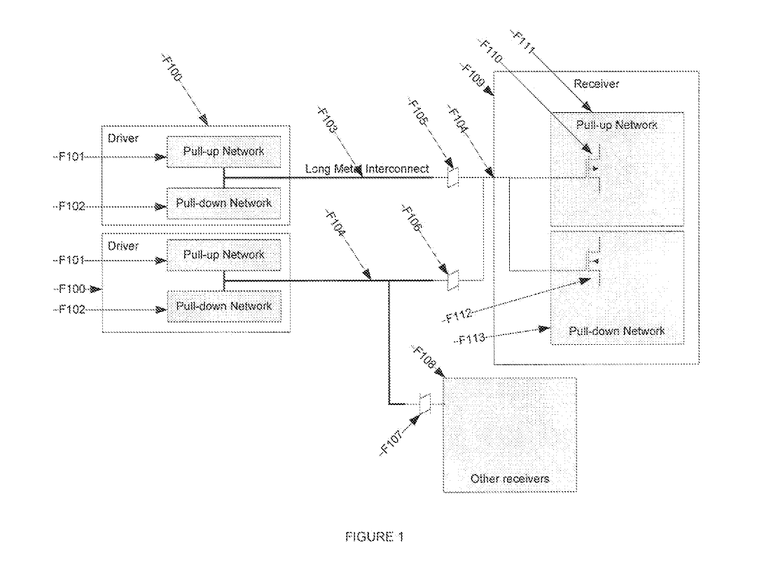

FIG. 1 shows a schematic of the building block of a programmable fabric utilizing a programmable via, according to an embodiment of the invention. In this figure, one or more programmable vias F105 may be located near the end of one or more long metal interconnects F103, which may be driven by driving circuit F100. The driving circuit (F100), may include a pull-up transistor network F101 and a pull-down transistor network F102. The long metal interconnect F103, F104 may include metal wires on one or more metal layers, and may also include metal vias. The programmable vias may be located at the end of this net, nearest the receiver F109 connected to a receiver input pin F104. This connection placement may be motivated by the high resistance of the programmable via and/or by the need to minimize the capacitance to be discharged through the programmable via. There could be one or more programmable vias at the terminus of the net, which may come from different sources, as illustrated by the second long metal interconnect net F104 connecting to the same input gate F104 through a different programmable via F106. Connecting one terminal of a set of n programmable vias, and programming only one to be in an ON state may be considered to be logically equivalent to an n-input multiplexor that is statically programmed to take one input. This is a building block that may be used in traditional FPGAs. The circuit consisting of programmable vias F105, F106 and the net connecting those programmable vias to the receiver input gate F104 may be considered to be equivalent to a 2-input multiplexor. This technique may be generalized to any number of inputs.

Additionally, a single logical output may fan-out to multiple programmable vias, as illustrated in FIG. 1 where net F104 goes to a third programmable via F107 and through that via to the receiver circuit F108. Unlike the fan-in case, where only one of a set of n programmable vias connected to a common input can be ON, in the fan-out case, any or all of the fan-out programmable vias can be ON. This is how the fan-out within the user design can be achieved in the programmed part.

Static CMOS circuits may have inputs pins F104 that may connect to the gate of a single logical transistor F110 in a pull-up transistor network F11 and to the gate of a single logical transistor F112 in a pull-down network, F113. In static CMOS circuits, the pull-up transistor network may be built using PMOS transistors, and the pull-down network may be built using NMOS transistors. To minimize input capacitance, the input transistors may be made small. A single logical transistor may comprise one or more physical transistors that may have identical port connections.

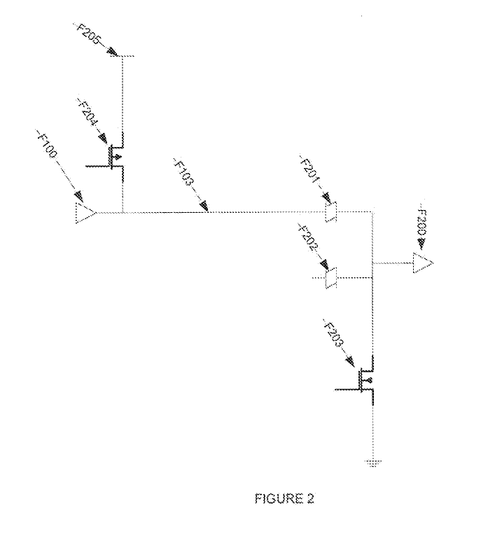

FIG. 2 illustrates one embodiment of a programming circuit for an IC using programmable vias. FIG. 2 illustrates a driving gate, F100, that fans out to a receiving gate F200 using a long metal interconnect F100. As illustrated in FIG. 1, this net F100 may often fan out to multiple receiving gates, but only one is illustrated. One of the receiving gates F200 is illustrated in more depth, including programmable vias F201, F202 connected to the receiving gate F200. A programming pull down transistor F203 is shown connected to the same electrical node as the gate input and the programmable via terminals. This pull-down transistor F203 may be turned on to hold the terminal of the programmable via to a low voltage when programming. Because it is connected to multiple programmable vias, the single transistor can be used to program any of the programmable vias (F201 and F202) associated with that receiving gate (F200). Additionally, this embodiment of a programming circuit may include another transistor, this one shown in FIG. 2 as a pull-up programming transistor F204 connected to the driving output of the net and connected to a programming voltage F205. Because this driver fans out to multiple programmable vias, this single transistor can be used to program multiple programmable vias. In this construction, a unique programmable via may be determined by enabling one pair of programming transistors consisting of a pull-up programming transistor and a pull-down programming transistor. The number of programming transistors may, therefore, be significantly reduced, to the sum of the average physical fan-in and average physical fan-out of the circuit, in some embodiments of the invention.

The voltages used to program programmable vias may be too large to be compatible with high-performance, low-voltage transistors used in most IC technology. Therefore, the programming transistors may be differentiated by having a thicker gate oxide, or other structural modification to deal with the larger voltages and to shield the sensitive transistors from the high voltage. Since thin oxide gates are the most sensitive to higher voltages, the pull-down programming transistor may be placed on the gate-side of the device, because keeping this node at a low voltage may prevent the gates of the non-programming logic from being damaged. This is illustrated in FIG. 2, where the programming pull-up transistor F204 may need to tolerate the higher voltage, and therefore may need to have some voltage protection.

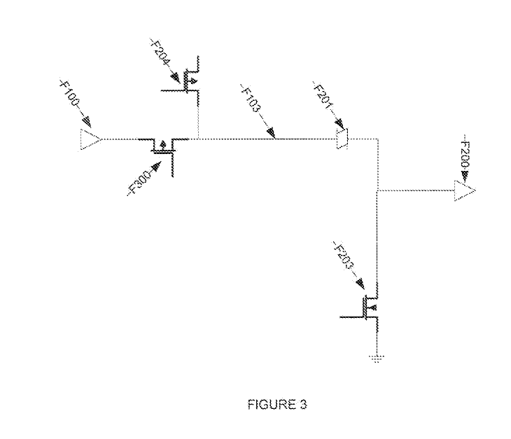

FIG. 3 illustrates an alternative embodiment that may be used to protect the output device by inserting a high-voltage transistor F300 between the driver F100 and the programming pull-up transistor F204. This transistor may be enabled only when the programming stage is complete, and the high programming voltage is not going to be connected to the net, and it is safe to connect the output driver F100 to the net F103.

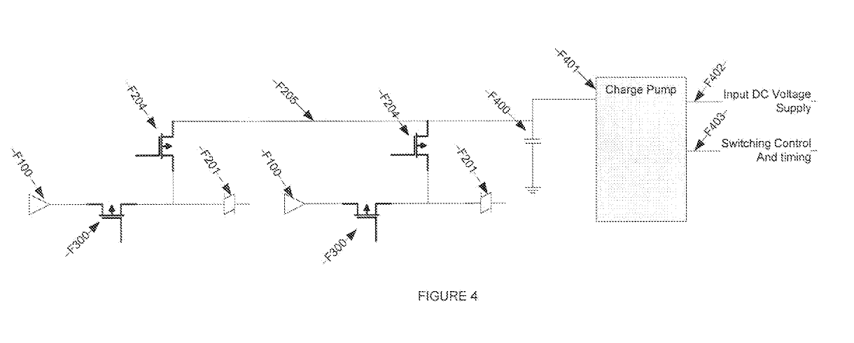

FIG. 4 illustrates an embodiment of the invention that may include a programming power supply F205 connected to a multiplicity of programmable pull-up transistors F204. The voltage on the supply rail may be held by a capacitor F400. The capacitor may be used to limit the amount of current that can pass through the programming transistors and the programmable via F201 when the via switches to the ON state. The voltage may be generated by a charge pump F401 that may take a low voltage DC supply F402 and timing and control signals F403, and which may generate the high voltage charge on its output. The capacitor F400 can be the output stage of the charge pump F401 or a separate device. The switch control and timing signals F403 may be able to be manipulated to thereby manipulate the output voltage as a function of time. The switch control and timing signals may, in some embodiments, include a clock or other periodic signal, and the variation of the frequency of that clock may be used to create a different output voltage function. This output voltage function may be useful for the reliable programming of programmable vias.

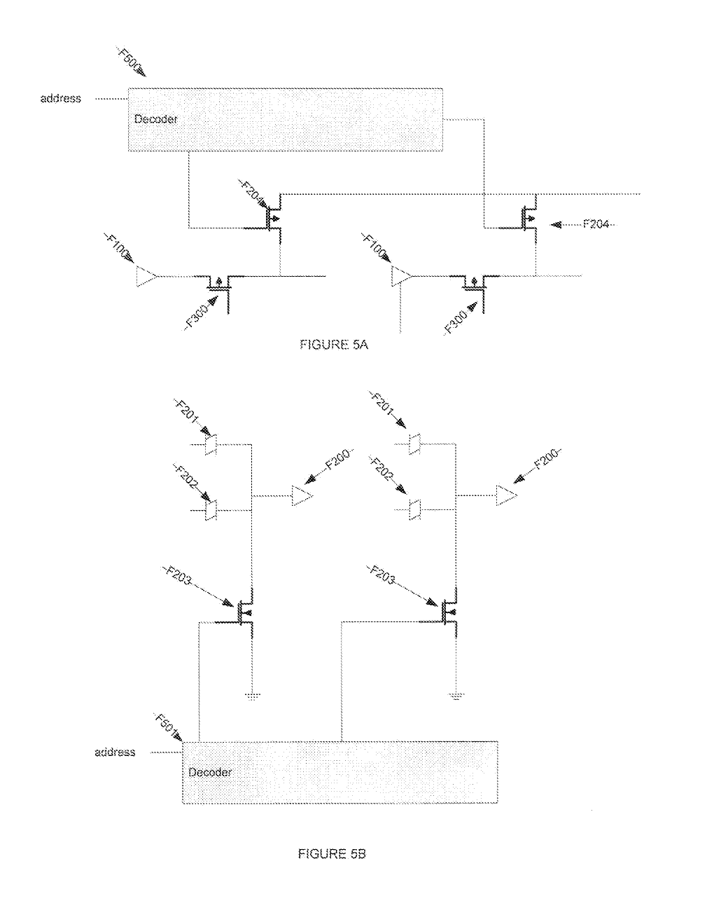

FIGS. 5A and 5B illustrate the connection of pull-up programming transistors F204 to address decoder F500, and pull-down programming transistors F203 to decoders F501, according to various embodiments of the invention. This may enable the user to connect the programming voltage across a specific programmable via. The pull-up and pull-down transistors can be partitioned arbitrarily into decoding sets and may then be connected to the decoders. In order for the device to be deterministically programmed, every programmable via may need to have a unique correspondence to a pair of programming transistors, one pull-up and one pull down. Only one of the programming pull-up transistors that connect to a single programming voltage supply may be enabled simultaneously. If this constraint is not complied with, the first programmable via to change to the ON state may discharge the output stage, and the voltage may not be present to program the second enabled programmable via. More than one pair of decoders and more than one programming voltage may be placed on the IC, and this may enable one to improve the time it takes to program the device.

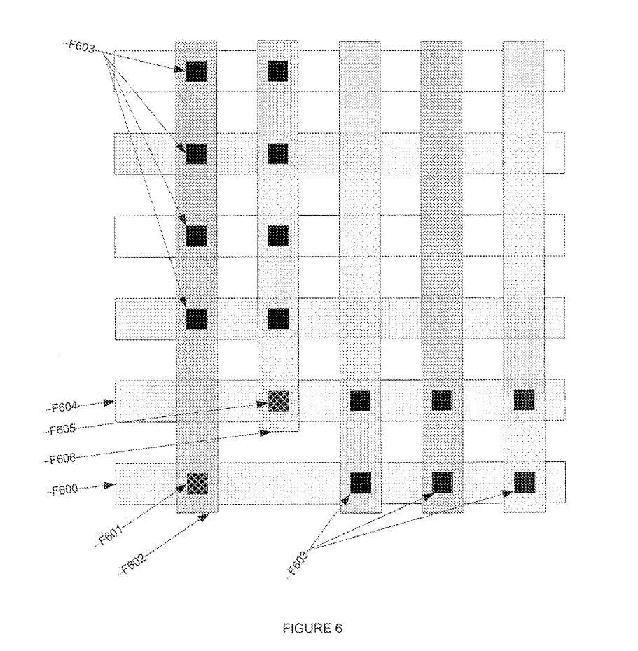

FIG. 6 illustrates some of the layout aspects of various embodiments of the invention. First, to maximize the flexibility of the programming of the device, it may be desirable to pack as many programmable vias as possible into a given area, but this may need to be done within the constraints of the programmable vias and the needs of the customer for programming flexibility. FIG. 6 illustrates a net composed of a wire segment F600, a non-programmable via F601 connecting that first wire segment to a second wire segment F602 on an adjacent metal layer. This net may connect to programmable vias F603 that may connect to metal wires running in two different directions, which may result in improved circuit routability. This kind of layout may be fully compatible with the layout of a neighboring net in a similar manner, as illustrated by metal wire segments F604 and F606, connected together with non-programmable via F605.

Various embodiments of the invention have now been described in connection with the accompanying figures, but the invention is understood to encompass variations and modifications of the above embodiments, as may be apparent to one of ordinary skill in the art.

I claim:

1. A semiconductor device comprising:
a programmable via comprising a material that can assume non-volatile resistive and conductive states; and
a transistor having two drain/source terminals and agate terminal, wherein the transistor is electrically connected to the programmable via on one drain/source terminal and to a conductor carrying a programming voltage on the other drain/source terminal.

2. The semiconductor device according to claim 1, wherein the transistor has an oxide thickness sufficient to tolerate the magnitude of the programming voltage.

3. The semiconductor device according to claim 1, wherein the voltage on the gate terminal is modulated to create the required voltage across the programmable via to program the via into a conductive or non-conductive state.

4. The semiconductor device according to claim 1, further comprising a charge pump configured to generate the programming voltage.

5. The semiconductor device according to claim 4, wherein the charge pump includes one or more control inputs, and wherein the charge pump is configured to permit the programming voltage to be controlled by varying one or more of the one or more control inputs of the charge pump.

6. A semiconductor device comprising:
one or more programmable vias, comprising a material that can assume non-volatile resistive and conductive states; and
one or more pairs of transistors, comprising a pull-up transistor and a pull-down transistor, wherein each pair corresponds with one of the one or more programmable vias.

7. The semiconductor device according to claim 6, wherein the pull-up transistor is electrically connected to the programmable via and to a first programming voltage and the pull-down transistor is electrically connected to the programmable via and a second programming voltage.

8. The semiconductor device according to claim 7, wherein the second programming voltage is a ground voltage.

9. The semiconductor device according to claim 6, further comprising:
one or more pull-up decoders configured to enable one of a set of two or more pull-up transistors, and
one or more pull-down decoders configured to enable one of a set of two or more pull-down transistors.

10. A semiconductor device comprising:
a set of more than one programmable vias, each having a first terminal and a second terminal, and
a set of transistors,
wherein the first terminal of each programmable via in the set is connected to a wire, wherein that wire is connected to gates of the set of transistors in a first network configuration and is further connected to gates of the set of transistors in a second network configuration, where the first network configuration and second network configuration have complementary topologies.

11. The semiconductor device according to claim 10, wherein the second terminal of each programmable via is connected to source terminals of a number of PMOS transistors and to source terminals of the same number of NMOS transistors.

12. A semiconductor device comprising:
a first wire segment on a first metal layer;
a set of two or more second wire segments, on a second metal layer, running in a parallel direction to each other, and running in a direction perpendicular to the first wire segment;
a set of two or more programmable vias, each connected to the first wire segment and to one of the second wire segments.

13. The semiconductor device according to claim 12, wherein the first wire segment is connected to a further wire segment on said second metal layer through a non-programmable via.

14. A method of programming a semiconductor device, the semiconductor device including at least one programmable via, at least one programming pull-up transistor and at least one programming pull-down transistor, the method comprising turning on the pull-up transistor and turning on the pull-down transistor to provide a programming voltage across the programmable via.

15. The programming method according to claim 14, wherein one of a set of more than one programming pull-up transistors is configured to be enabled by a binary number and wherein one of a set of pull-down transistors is configured to be enabled by a second binary number.

16. A method of programming a semiconductor device, the semiconductor device including at least one programmable via and a charge pump configured to generate a programming voltage, the method comprising providing one of at least two switching frequencies to the charge pump and providing the programming voltage to the programmable via.
